(19) United States
(12) Patent Application Publication
(10) Pub. No.: US 2026/0201561 A1
(43) Pub. Date: Jul. 16, 2026

(54) LOAD-LOCK APPARATUS

(71) Applicant: NISSIN ION EQUIPMENT CO, LTD., Koka-City (JP)

(72) Inventor: Masatoshi ONODA, Koka-City (JP)

(73) Assignee: NISSIN ION EQUIPMENT CO, LTD., Koka-City (JP)

(21) Appl. No.: 19/428,640

(22) Filed: Dec. 22, 2025

(30) Foreign Application Priority Data
Jan. 16, 2025 (JP) 2025-006122

(51) Int. Cl. C23C 16/458; C23C 14/48; C23C 14/54; C23C 14/56; C23C 16/46; H10P 72/76

(52) U.S. Cl. CPC C23C 16/4583; C23C 14/48; C23C 14/541; C23C 14/566; C23C 16/463; H10P 72/7618

(57) ABSTRACT

A load-lock apparatus includes a fixed part, and a movable part that moves to connect with the fixed part to form a load-lock chamber therebetween. The fixed part and/or the movable part includes a cooling gas inlet to supply a cooling gas into the load-lock chamber. The movable part includes a stage that supports a wafer, a cooling plate that cools the wafer, a base member that supports one of the stage and the cooling plate, a second support shaft connected to the other one of the stage and the cooling plate, a second drive structure that moves the second support shaft, a first support shaft connected to the base member, and a first drive structure that moves the first support shaft, the second support shaft, and the second drive structure together.

### CROSS REFERENCE TO RELATED APPLICATIONS

This application is based on and claims priority from Japanese Patent Application No. JP 2025-006122 filed on January 16, 2025 in the Japan Patent Office, the contents of which being incorporated by reference herein in its entirety.

### BACKGROUND

### Field

The present disclosure relates to a load-lock apparatus configured to cool a wafer that has been processed under high temperature.

### 2.Description of Related Art

In a chemical vapor deposition apparatus and an ion implanter, a wafer heated to a high temperature in a process chamber may be subjected to a predetermined process, and before returning the wafer to a cassette arranged on an atmospheric side, the wafer may be cooled in a load-lock chamber.

### SUMMARY

According to an aspect of one or more embodiments, a load-lock apparatus may comprise a fixed part; and a movable part configured to move to connect with the fixed part to form a load-lock chamber therebetween. At least one of the fixed part or the movable part may comprise a cooling gas inlet configured to supply a cooling gas into the load-lock chamber. The movable part may comprise a stage configured to support a wafer, a cooling plate configured to cool the wafer, a base member configured to support either the stage or the cooling plate, a second support shaft connected to either the stage that is not supported by the base member or to the cooling plate that is not supported by the base member, a second drive structure configured to move the second support shaft, a first support shaft connected to the base member, and a first drive structure configured to move the first support shaft, the second support shaft, and the second drive structure together.

According to another aspect of one or more embodiments, a load-lock apparatus may comprise a stage configured to receive a wafer, a cooling plate configured to cool the wafer, a first base member configured to support the cooling plate, a second base member comprising one or more cooling gas inlets, a first support shaft connected to the first base member, a second support shaft connected to the stage, a second drive structure configured to move the second support shaft, and a first drive structure configured to move the first support shaft, the second support shaft, and the second drive structure together such that the second base member contacts the first base member to define a load-lock chamber therebetween. A cooling gas may be supplied to the load-lock chamber through the one or more cooling gas inlets to cool the wafer supported on the stage in the load-lock chamber.

### BRIEF DESCRIPTION OF THE DRAWINGS

The above and/or other aspects will become apparent and more readily appreciated from the following description of various embodiments, taken in conjunction with the accompanying drawings, in which:

FIG. 1 illustrates an example of a configuration view of a load-lock apparatus, according to some embodiments;

FIG. 2 illustrates an example of a state in which a movable part of the load-lock apparatus has moved downward from a state shown in FIG. 1, according to some embodiments;

FIG. 3 illustrates an example of a plan view of a cooling plate of the load-lock apparatus of FIG. 1, according to some embodiments;

FIG. 4 illustrates an example of a plan view of a stage of the load-lock apparatus of FIG. 1, according to some embodiments;

FIG. 5 illustrates an example of a flowchart representing a process of transferring a heated wafer to an atmosphere, according to some embodiments;

FIG. 6 illustrates an example of a diagram showing a positional relationship between a wafer and a cooling plate, according to some embodiments;

FIG. 7 illustrates an example of a plan view of a cooling plate, according to some embodiments;

FIG. 8 illustrates an example of a plan view of a cooling plate, according to some embodiments;

FIG. 9 illustrates an example of a plan view of a cooling plate, according to some embodiments;

FIG. 10 illustrates an example of a configuration view of a load-lock apparatus, according to some embodiments;

FIG. 11 illustrates an example of a configuration view of a load-lock apparatus, according to some embodiments;

FIG. 12 illustrates an example of a configuration view of a load-lock apparatus, according to some embodiments; and

FIG. 13 illustrates an example of a configuration view of a load-lock apparatus, according to some embodiments.

### DETAILED DESCRIPTION

Hereinafter, various embodiments of the present disclosure will be described with reference to the drawings. In all the drawings for explaining the various embodiments, common components are denoted by the same reference numerals, and repeated description thereof will be omitted for conciseness. The following embodiments do not unduly limit the contents of the present disclosure described in the appended claims. Further, all the components shown in the embodiments are not necessarily essential components of the present disclosure. Each drawing is a schematic view and is not necessarily intended to illustrate various dimensions strictly.

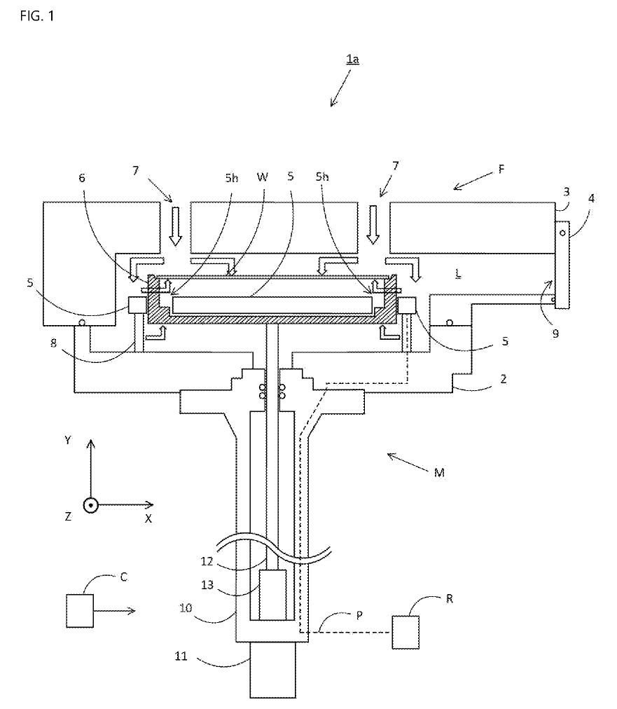

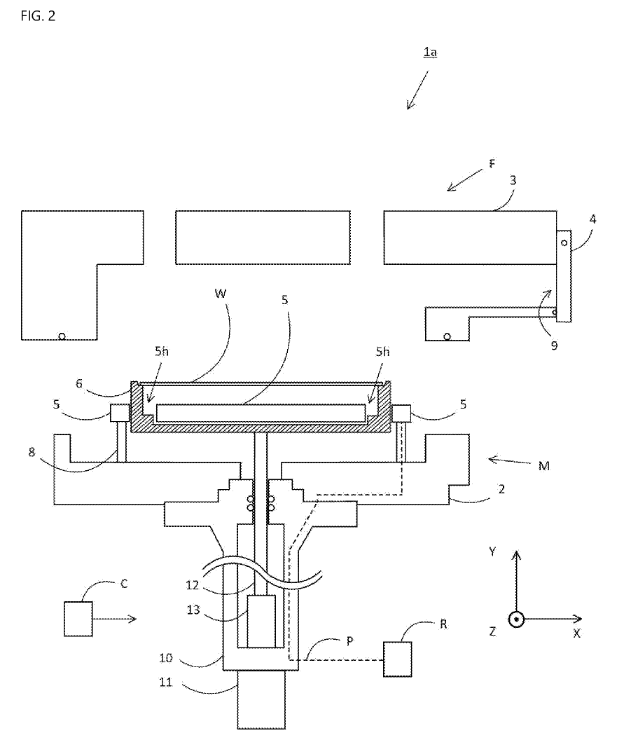

FIG. 1 illustrates an example of a configuration view of a load-lock apparatus, according to some embodiments. FIG. 2 illustrates an example of a state in which a movable part of the load-lock apparatus has moved downward from a state shown in FIG. 1, according to some embodiments. FIG. 1 shows an overall structure of a load-lock apparatus 1a. The load-lock apparatus 1a is divided vertically into a movable part M and a fixed part F. (See also FIG. 2). The movable part M includes components, such as a cooling plate 5 and a stage 6, that move vertically along a Y-axis. The fixed part F does not contain any vertically moving components.

The connection between the movable part M and the fixed part F changes as the movable part M moves. In FIG. 1, the movable part M and the fixed part F are connected, with a first base member 2 of the movable part M and a second base member 3 of the fixed part F touching to form a load-lock chamber L. In other words, when the movable part M is moved such that the movable part M and the fixed part F are connected, the first base member 2 of the movable part M and the second base member 3 of the fixed part F touch together to define the load-lock chamber L therebetween. In FIG. 2, the movable part M has been moved downward (in the -Y direction), resulting in a disconnected state between the movable part M and the fixed part F. When disconnected, a wafer W may be transferred between a process chamber (not shown) and the load-lock chamber L.

In FIG. 1, the fixed part F includes the second base member 3 and a flap valve 4. The second base member 3 forms a ceiling of the load-lock chamber L. At one end of the second base member 3, there is a loading port 9 that allows the wafer W to be transferred horizontally. The loading port 9 opens and closes by rotating the flap valve 4 around the Z-axis.

The second base member 3 may be equipped with one or more cooling gas inlets 7 for supplying cooling gas (such as nitrogen, argon, or other purge gases) into the load-lock chamber L. Although FIG. 1 shows two cooling gas inlets 7, the number is not limited to two and, in some embodiments, there may be three or more, or even just one. The position of the one or more cooling gas inlets 7 is not restricted to a position facing an outer edge of the wafer W. The cooling gas inlet 7 may also be placed at a position facing a center of the wafer. The term “cooling gas” gas refers to gas supplied for the purpose of controlling the temperature of a wafer, and the cooling gas is typically provided at a temperature lower than a temperature of the wafer W. In some cases, room-temperature gas may also be used as cooling gas.

The one or more cooling gas inlets 7 may be connected to a cooling gas source via a valve (not shown). To control the flow rate from the cooling gas source, a diffusion filter may be attached to the one or more cooling gas inlets 7. Adding a diffusion filter may reduce a flow rate of cooling gas supplied to the load-lock chamber L, helping to suppress particle movement inside the load-lock chamber L. In an embodiment, an adjustable opening restriction plate may be attached to the one or more cooling gas inlets 7 to regulate both the flow rate and the direction of the cooling gas supplied to the load-lock chamber L.

The movable part M includes the stage 6, the cooling plate 5, a support member 8, and the first base member 2. The stage 6 supports the wafer W, the cooling plate 5 cools the wafer, and the first base member 2 supports the cooling plate. The cooling plate 5 is supported by the first base member 2 via the support member 8, which may be a cylindrical part with side openings for cooling gas passage. In an embodiment, the cooling plate 5 may be larger than the stage 6 in the X direction as illustrated in FIG. 2.

The stage 6 is connected to a second support shaft 12 for vertical movement. The second support shaft 12 may be moved vertically by a second drive structure 13, which includes a drive source, such as a motor, an air supply, and/or exhaust, and a mechanism, such as a transfer gear, an actuator to move an air cylinder, etc.

The first base member 2 is connected to a first support shaft 10 for vertical movement. The first support shaft 10 supports the second drive structure 13. The first support shaft 10 may be moved vertically by a first drive structure 11, which also includes a drive source such as a motor and mechanism such as a transfer gear.

When the first drive structure 11 moves the first support shaft 10 vertically, the second drive structure 13, the second support shaft 12, the cooling plate 5, the stage 6, the support member 8, and the first base member 2 all move together with the first support shaft 10.

A cooling source R is located outside the load-lock apparatus 1a. A coolant flow path P runs from the cooling source R, through the first support shaft 10, the first base member 2, and the support member 8, and connects to a coolant flow path formed inside the cooling plate 5.

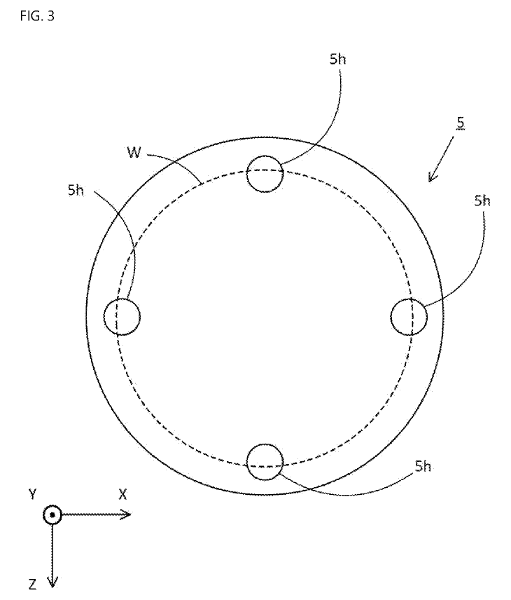

FIG. 3 is a top view of the cooling plate 5 shown in FIG. 1. The cooling plate 5 may be circular. The dashed circle represents an outline of the wafer W. In this view, the cooling plate 5 is larger than the wafer W, so the cooling plate 5 may cool the entire wafer from below.

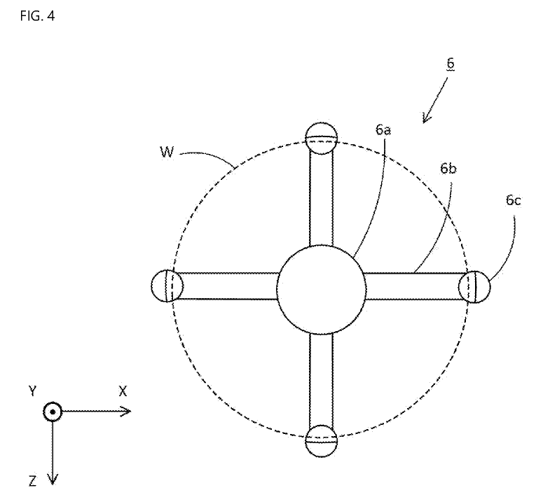

The cooling plate 5 has four insertion ports 5h. The support portions 6c of the stage 6, shown in FIG. 4, are inserted into the insertion ports 5h, respectively.

FIG. 4 is a top view of the stage 6 shown in FIG. 1. The dashed circle represents the outline of the wafer W. The stage 6 includes of a main body 6a connected to the second support shaft 12, four connecting arms 6b extending radially from the main body 6a, and a support portion 6c attached to one end of each of the four connecting arm 6b and extending in the Y-axis direction. Each tip of the support portions 6c contacts and holds a back surface of the wafer W. To help position a misaligned wafer, the tips of the support portion 6c may be tapered.

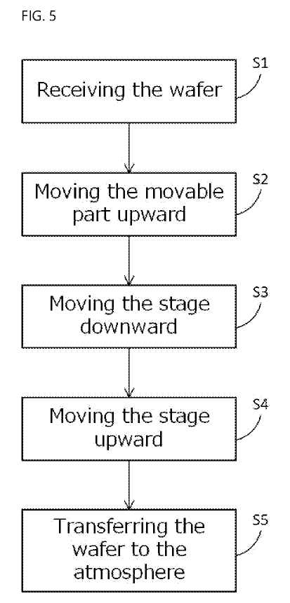

FIG. 5 is a flowchart showing a sequence for transferring a heated wafer W to an atmosphere. First, the movable part M is in the state shown in FIG. 2. The high-temperature wafer W processed in the process chamber is transferred to the stage 6 and the stage 6 receives the wafer W (S1). After the wafer W is transferred to the stage 6, the movable part M moves upward and connects to the fixed part F (S2). After the connection, the second drive structure 13 moves the second support shaft 12 downward, causing the stage 6 to descend within the load-lock chamber L (S3). As the stage 6 descends, the wafer W moves toward the cooling plate 5 within the load-lock chamber L. Cooling gas is supplied into the load-lock chamber L from the one or more cooling gas inlets 7 of the second base member 3, either during or after the descent of the stage 6. Operations S4 and S5 are described below.

In an embodiment, after cooling gas is supplied to the load-lock chamber L through the one or more cooling gas inlets 7, the cooling gas flows along the path indicated by arrows in FIG. 1 and may be supplied to both the upper and lower surfaces of the wafer W. In other words, the cooling gas may circulate around the stage 6 which supports the wafer W.

Some of the cooling gas supplied from above the wafer W cools an upper surface of the wafer W. The remainder travels along the side wall of the load-lock chamber L and moves downward. As shown in FIG. 4, the stage 6 only partially supports the wafer W from below. In other words, the stage 6 partially supports the wafer W by the support portions 6c. Because the stage 6 does not support an entire circumference of the wafer, cooling gas passing through the stage 6 may reach the lower surface of the wafer.

Some cooling gas that moves below the cooling plate 5 may pass through a gap formed between the insertion port 5h of the cooling plate 5 and the support portion 6c of the stage 6, and may be supplied to the lower surface of the wafer W.

Supplying cooling gas to the lower surface of the wafer W improves the thermal conductivity between the cooling plate 5 and the wafer W. Bringing the wafer W closer to the cooling plate 5 further enhances cooling efficiency.

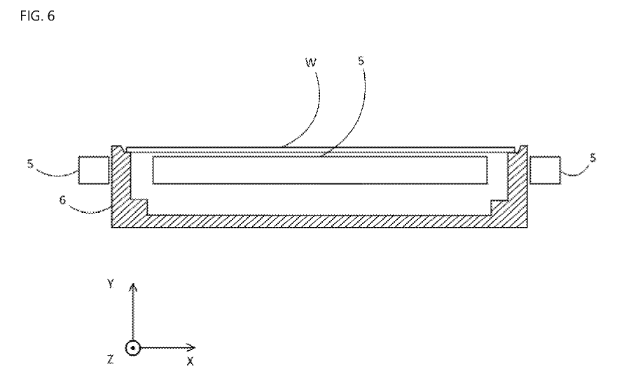

FIG. 6 shows the state when the wafer W is brought close to the cooling plate 5. The wafer W may deform slightly as the wafer W cools. If the wafer W deforms significantly, a back surface of the wafer W may touch a surface of the cooling plate 5, causing rubbing. The rubbing may generate particles inside the load-lock chamber L and may scratch the back surface of the wafer W. To prevent particle generation and scratching, a small gap is maintained between the wafer W and the cooling plate 5, as shown in FIG. 6.

However, an acceptable amount of particles may vary depending on the wafer processing type. The amount of wafer deformation also depends on the wafer material and the temperature difference during cooling. Considering these factors, it may not always be necessary to maintain a gap between the wafer and the cooling plate. In some examples, the wafer W may be brought into direct contact with the cooling plate 5. The temperature difference during cooling refers to the difference between the temperature of the wafer W during heat treatment in the process chamber and a target temperature of the wafer W during cooling in the load-lock chamber L.

Returning to FIG. 5, after the wafer W is cooled, the stage 6 rises (S4). As the stage 6 rises, the wafer W moves away from the cooling plate 5, increasing the distance between the stage 6 that supports the wafer W and the cooling plate 5.

Next, the flap valve 4 opens, and a hand of an atmospheric robot enters the load-lock chamber L to transfer the wafer W to the atmospheric side. As the stage 6 rises, the gap between the wafer W and the cooling plate 5 widens. The robot hand moves below the wafer W, lifts the wafer W, and transfers the wafer W to the robot hand. The robot hand then moves outside the flap valve 4 (to the atmospheric side), and the wafer W is transferred to the atmospheric side (S5). For example, the wafer W may be transferred to a downstage chamber that is at atmospheric pressure.

The process shown in the flowchart of FIG. 5 may be managed by a controller C in FIG. 1. The controller C may include a processing unit and a memory unit. The processing unit may be a microprocessor, CPU, microcontroller, hardware control logic, or a combination of these. Multiple processing units may also be used. The memory unit may store program code for functions such as data storage, data processing, wafer transfer control, and threshold values for pressure in the load-lock chamber L. The processing unit accesses the program code in memory to execute these functions.

In an embodiment, the controller C may be a dedicated device for controlling each part of the load-lock apparatus 1a. In an embodiment, the controller C may be integrated into a controller for a chemical vapor deposition apparatus or an ion implanter equipped with the load-lock apparatus 1a. Note that the load-lock apparatus 1a may be used not only with the chemical vapor deposition apparatus or the ion implanter described above, but also with other apparatuses that perform high-temperature processing of wafers in a process chamber.

As described above, in an embodiment, the cooling plate 5 and the stage 6 are arranged on the movable part M side, and cooling gas is supplied into the load-lock chamber L. The relative position between the cooling plate 5 and the stage 6 may be adjusted on the movable part M side. Because cooling gas is present between the wafer W and the cooling plate 5, thermal conductivity between the components increases, improving cooling efficiency. Bringing the cooling plate 5 and the stage 6 closer together further enhances cooling. Since both are on the movable part M side, adjusting the relative positions of the cooling plate 5 and the stage 6 is easier than if the cooling plate 5 were on the fixed part F side.

In an embodiment, a timing for supplying cooling gas may be in parallel with bringing the wafer W closer to the cooling plate 5, or after the wafer W has been brought close. To bring the wafer W closer, the stage 6 supporting the wafer W may be moved downward, causing an upward force on the wafer. While the upward force acts, a risk of the wafer falling from the stage 6 increases. Supplying cooling gas during this time may further increase this risk, so it is advantageous to supply cooling gas after the wafer W has been brought close to the cooling plate 5.

On the other hand, to ensure reliable supply of cooling gas between the wafer W and the cooling plate 5, it may be advantageous to supply cooling gas in parallel with bringing the wafer W closer. In an embodiment, cooling gas supply may start before moving the wafer W closer, so that cooling gas is reliably supplied between the wafer W and the cooling plate 5.

If cooling gas supply continues, the pressure inside the load-lock chamber L may reach a threshold value. The threshold value may be predetermined. If the pressure becomes excessively higher than atmospheric pressure, the flap valve 4 closing the loading port 9 may open due to the pressure difference, releasing cooling gas to the atmosphere, which is undesirable.

If nitrogen gas is used as the cooling gas, a large amount of nitrogen may be released to the atmosphere, raising concerns about nitrogen poisoning for workers during maintenance. To prevent this release, it is advantageous to stop cooling gas supply before the pressure inside the load-lock chamber L reaches the threshold value.

To stop cooling gas supply, the pressure inside the load-lock chamber L may be measured. A threshold value lower than the pressure at which the flap valve 4 opens may be stored in the controller C. The controller C may compare the threshold and measured values, and when the measured value exceeds the threshold, the controller C may control the cooling gas to store the supply of the cooling gas.

Instead of stopping cooling gas supply, the pressure inside the load-lock chamber L during wafer cooling may be kept below the threshold by using a pump. In this case, a roughing pump may be connected to the load-lock chamber L to exhaust some of the cooling gas supplied into the load-lock chamber L.

The connection location of the roughing pump may be set opposite to a position at which the cooling gas is supplied, so that cooling gas flows from one end to the other within the load-lock chamber L. Specifically, in the configuration of FIG. 1, cooling gas is introduced from the ceiling (i.e., top), and the roughing pump may be connected near the floor (i.e., bottom) of the load-lock chamber L to exhaust the gas.

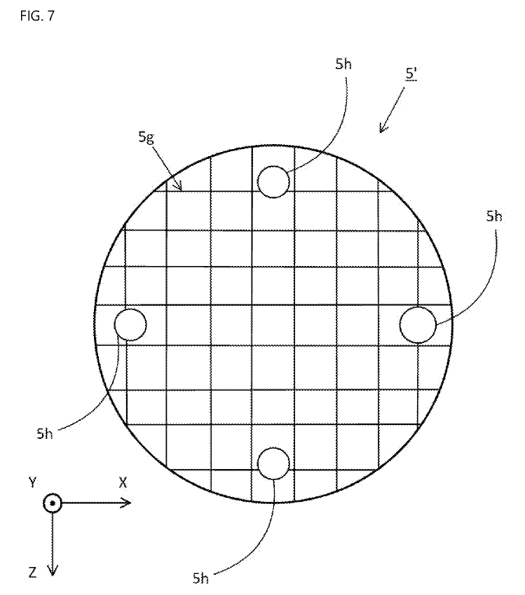

FIG. 7 shows a cooling plate 5’ according to some embodiments. If a small gap is maintained between the wafer W and the cooling plate 5, there may be concern that cooling gas cannot reach the entire lower surface of the wafer W. To address this concern, grooves 5g may be provided across a surface of the cooling plate. The grooves 5g allow cooling gas to travel along the grooves 5g and reach the entire lower surface of the wafer W. The grooves 5g may be lattice-shaped, as shown in FIG. 7, but embodiments are not limited thereto and, in some embodiments, other designs may be used. In an embodiment, the grooves 5g may be connected to the insertion ports 5h of the cooling plate 5. By connecting the grooves 5g to the insertion ports 5h, cooling gas passing through the insertion ports 5h may travel along the grooves 5g and be more easily supplied to the lower surface of the wafer W.

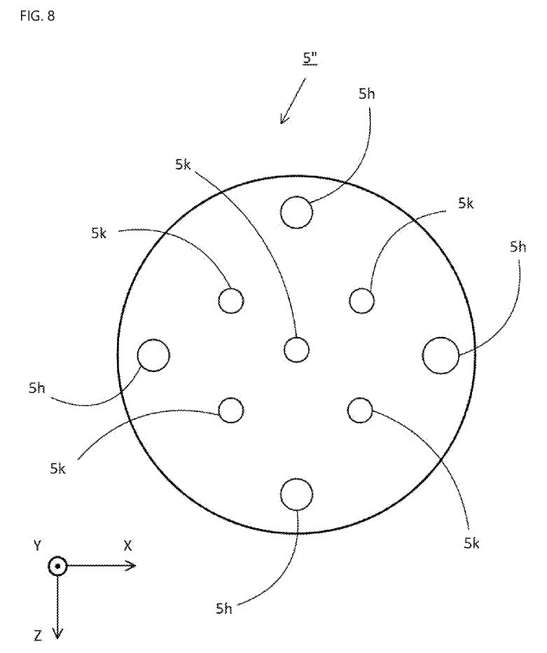

FIG. 8 shows s cooling plate 5’’ according to some embodiments. In the cooling plate shown in FIG. 3, cooling gas is supplied from below via the insertion ports 5h, which are only at locations corresponding to the support portions 6c of the stage 6. To increase the supply points for cooling gas from below and ensure gas reaches the entire lower surface of the wafer W, openings 5k may be additionally be provided in the cooling plate 5, as shown in FIG. 8.

The configuration in FIG. 8 uses multiple small openings 5k, but the size of the openings 5k may be increased to provide larger openings. However, making the openings larger reduces the area of the cooling plate 5 facing the wafer W, which may decrease cooling efficiency.

In FIG. 7, the configuration with grooves 5g in the cooling plate 5 to supply cooling gas to the entire lower surface of the wafer W has been described. However, if only a small amount of cooling gas is supplied between the cooling plate 5 and the wafer W, the improvement in cooling efficiency may be insufficient.

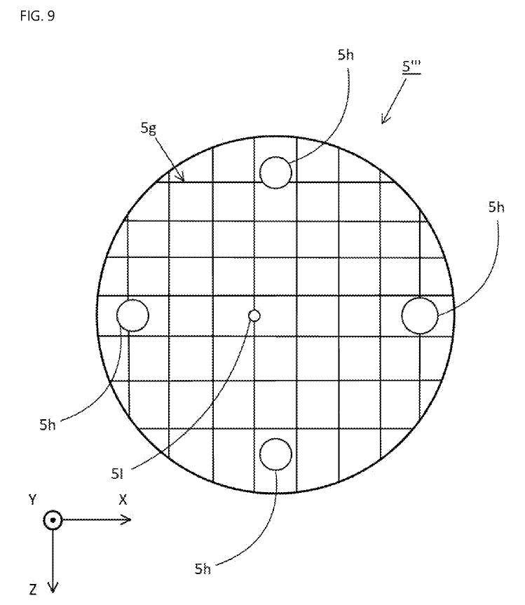

FIG. 9 illustrates an example of a plan view of a cooling plate 5’’’, according to some embodiments. As shown in FIG. 9, the cooling plate 5’’’ may include a gas inlet 5I to supply cooling gas from the cooling plate 5’’’ toward the lower surface of the wafer W. In FIG. 9, only one gas inlet 5I is shown, but embodiments are not limited thereto and, in some embodiments, multiple inlets 5I may be used. Like the coolant flow path, a gas supply path for gas introduction may be formed inside the cooling plate 5’’’.

The cooling plate configurations described in FIGS. 7 to 9 are not limited to those shown. For example, in an embodiment, the structures in FIGS. 7 and 8 may be combined so that the cooling plate 5 includes both grooves 5g and openings 5k. In an embodiment, the structures in FIGS. 8 and 9 may be combined so that the cooling plate 5 includes both openings 5k and gas inlets 5I.

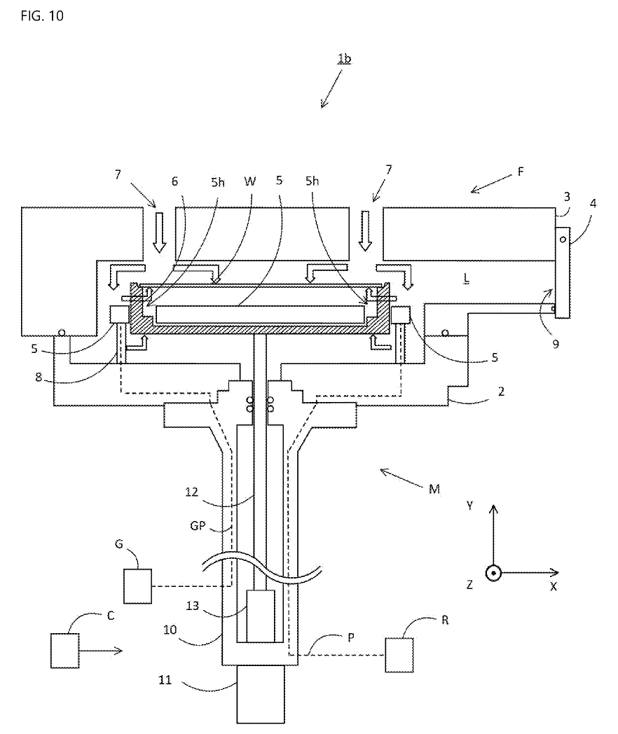

FIGS. 10-13 illustrate example of configuration views of load-lock apparatuses, according to some embodiments. In an embodiment, as shown in FIG. 10, cooling gas may be supplied to the cooling plate 5 from an external gas source G. The cooling gas from the external gas source G passes through a supply path GP formed in the first support shaft 10, the first base member 2, and the support member 8, and is supplied to the cooling plate 5.

When supplying cooling gas between the cooling plate 5 and the wafer W, it is advantageous to supply the gas from the cooling plate 5. On the other hand, although the efficiency of supplying cooling gas to the lower surface of the wafer W may decrease, cooling gas may be supplied from the first base member 2 or the stage 6, and then supplied between the cooling plate 5 and the lower surface of the wafer W via the cooling plate 5.

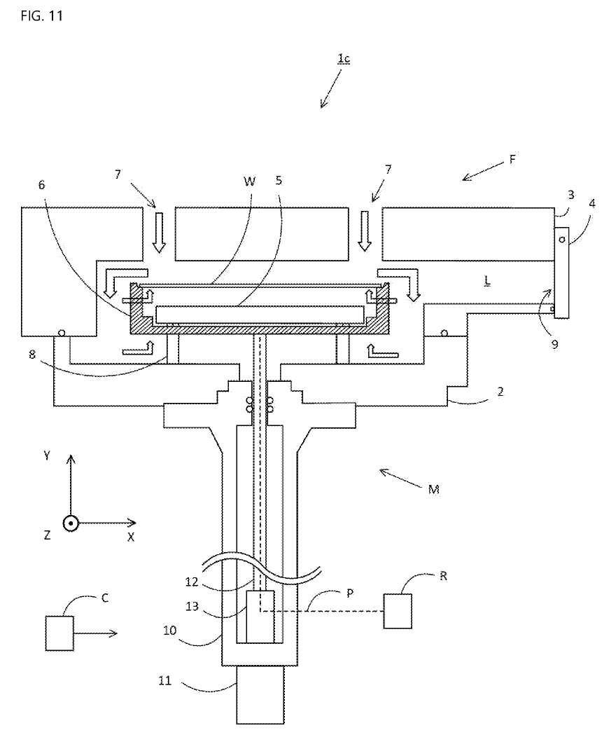

In the configurations shown in FIGS. 1 and 10, the cooling plate 5 used to cool the entire lower surface of the wafer W is larger than the stage 6 and the wafer W that is supported by the stage 6. However, for cooling purposes, the cooling plate 5 may be smaller than the stage 6 and the wafer W that is supported by the stage 6. In the load-lock apparatus 1c shown in FIG. 11, a cooling plate 5 smaller than the stage6 is used.

In the configuration of FIG. 11, since the cooling plate 5 is smaller than the stage 6 that supports the wafer W, cooling efficiency may decrease compared to the embodiments illustrated in FIGS. 1 and 10. However, the configuration illustrated in FIG. 11 simplifies a structure of the cooling plate. By making the cooling plate 5 smaller, the cooling plate 5 may be placed inside the stage 6, eliminating the need for insertion ports 5h.

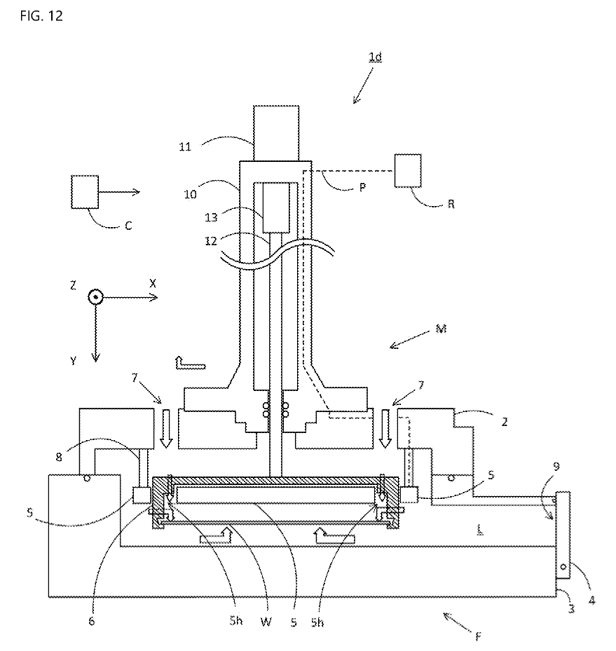

In the embodiments illustrated in FIGS. 1-11, the movable part M was described as moving downward when transferring the wafer W from the load-lock chamber L to the process chamber. However, as shown in the load-lock apparatus 1d in FIG. 12, the movable part M may also move upward during wafer transfer.

In this configuration, one or more cooling gas inlets 7 may be provided in the movable part M to supply cooling gas from above the wafer W. If cooling gas is supplied only from below, it may be necessary to hold the upper edge of the wafer W with pins or similar components, which may complicate the structure and increase costs. When supplying cooling gas from either the upper or lower side, it is advantageous to supply gas from above. However, this advantage does not exclude supplying gas from below; supplementary supply from below may also be used.

Furthermore, in the configuration of FIG. 12, an L-shaped nozzle may be installed in the second base member 3 forming the floor of the load-lock chamber L, allowing cooling gas to be supplied from the side (including both upper and lower surfaces) or from above the wafer W through the nozzle.

Cooling gas may be supplied from the fixed part F side, as shown in FIGS. 1 to 11 and FIG. 13, or from the movable part M side, as shown in FIG. 12. In some embodiments, cooling gas may be supplied from both the fixed part F and movable part M.

In the embodiments illustrated in FIGS. 1-13, the distance between the wafer W and the cooling plate 5 in the Y-axis direction was adjusted by moving the stage 6. However, the configuration may also be changed so that the cooling plate 5 moves and the stage 6 remains fixed.

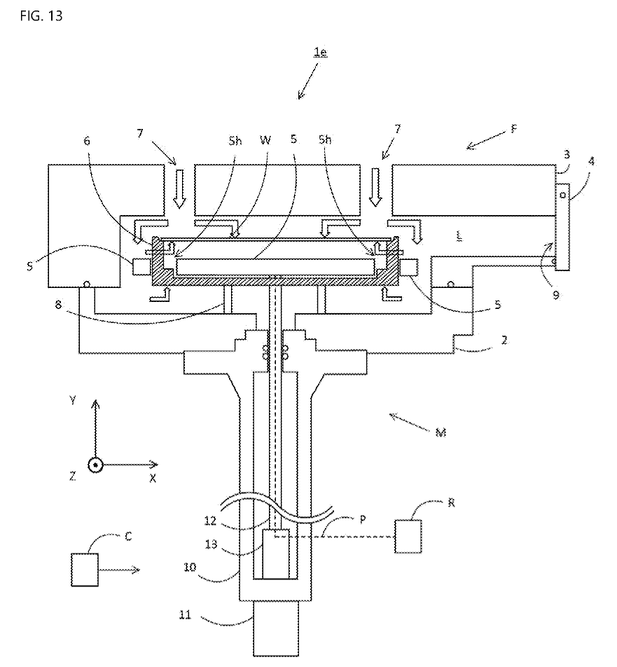

In the load-lock apparatus 1e shown in FIG. 13, the distance between the wafer W and the cooling plate 5 along the Y-axis is adjusted by moving the cooling plate 5 itself. In this configuration, the second support shaft 12 is connected to the cooling plate 5, and the support member 8 is connected to the stage 6. Coolant may be supplied to the cooling plate 5 through the second support shaft 12. Other load-lock apparatuses may also use a configuration in which the cooling plate is moved instead of the stage, as shown in FIG. 13.

In the embodiments illustrated in FIGS. 1-13, the first support shaft 10 was described as enclosing part of the second support shaft 12. This arrangement allows part of the second support shaft 12 to be housed inside the first support shaft 10, which simplifies the structure around the first support shaft 10.

However, if a more complex structure around the first support shaft 10 is acceptable, the entire second support shaft 12 may be positioned outside the first support shaft 10. In this case, if the second drive structure 13 is supported by the first support shaft 10, the second support shaft 12 may be moved together with the first support shaft 10.

In the embodiments illustrated in FIGS. 1-13, the wafer W was assumed to be made of silicon or silicon carbide, but in some embodiments, the wafer W may be a glass substrate. The shape of the wafer is not limited to a circle, and in some embodiments, the wafer W may also be rectangular.

It should be understood that embodiments are not limited to the various embodiments described above, but various other changes and modifications may be made therein without departing from the spirit and scope thereof as set forth in appended claims.

What is claimed is:

1. A load-lock apparatus comprising:
a fixed part; and
a movable part configured to move to connect with the fixed part to form a load-lock chamber therebetween,
wherein at least one of the fixed part and the movable part comprises a cooling gas inlet configured to supply a cooling gas into the load-lock chamber, and
wherein the movable part comprises:
a stage configured to support a wafer,
a cooling plate configured to cool the wafer,
a base member configured to support either the stage or the cooling plate,
a second support shaft connected to either the stage that is not supported by the base member or to the cooling plate that is not supported by the base member,
a second drive structure configured to move the second support shaft,
a first support shaft connected to the base member, and
a first drive structure configured to move the first support shaft, the second support shaft, and the second drive structure together.

2. The load-lock apparatus according to claim 1, wherein the cooling plate comprises at least one insertion port through which a part of the stage is inserted.

3. The load-lock apparatus according to claim 2, wherein the cooling plate comprises grooves connected to the at least one insertion port to distribute the cooling gas to a lower surface of the wafer.

4. The load-lock apparatus according to claim 1, wherein the cooling plate comprises a groove on a surface of the cooling plate that faces the wafer.

5. The load-lock apparatus according to claim 1, wherein the cooling plate comprises an opening penetrating an upper surface and a lower surface of the cooling plate, through which the cooling gas passes.

6. The load-lock apparatus according to claim 1, wherein the first support shaft includes a part of the second support shaft.

7. The load-lock apparatus according to claim 1, wherein the cooling plate comprises a gas inlet configured to supply the cooling gas to the wafer supported by the stage.

8. The load-lock apparatus according to claim 1, wherein the cooling plate is larger than the stage and is configured to cool an entire lower surface of the wafer.

9. The load-lock apparatus according to claim 1, wherein the cooling plate is smaller than the stage and is arranged inside the stage.

10. The load-lock apparatus according to claim 1, further comprising a controller that is configured to stop the supply of the cooling gas to the load-lock chamber when a measured pressure inside the load-lock chamber exceeds a threshold value.

11. The load-lock apparatus according to claim 1, wherein:
the cooling plate and the stage are both arranged on the movable part, and
a position of the cooling plate and a position of the stage are adjustable relative to each other.

12. The load-lock apparatus according to claim 1, wherein the cooling plate is moved to adjust a distance between a position of the wafer that is supported by the stage and a position of the cooling plate, while a position of the stage remains fixed.

13. The load-lock apparatus according to claim 1, wherein:
the fixed part comprises the cooling gas inlet,
the base member of the movable part supports the cooling plate, and
the second support shaft is connected the stage.

14. The load-lock apparatus according to claim 1, wherein:
the base member of the movable part is a first base member,
the fixed part comprises a second base member and a flap valve,
the second base member is moved to touch the first base member to define the load-lock chamber in a space between the first base member and the second base member, and
the flap valve is configured to open and close the load-lock chamber.

15. A load-lock apparatus comprising:
a stage configured to receive a wafer,
a cooling plate configured to cool the wafer,
a first base member configured to support the cooling plate,
a second base member comprising one or more cooling gas inlets,
a first support shaft connected to the first base member,
a second support shaft connected to the stage,
a second drive structure configured to move the second support shaft, and
a first drive structure configured to move the first support shaft, the second support shaft, and the second drive structure together such that the second base member contacts the first base member to define a load-lock chamber therebetween,
wherein a cooling gas is supplied to the load-lock chamber through the one or more cooling gas inlets to cool the wafer supported on the stage in the load-lock chamber.

16. The load-lock apparatus according to claim 15, wherein the second base member comprises a flap valve, and
wherein the flap valve is configured to open to receive the wafer onto the stage in the load-lock chamber and to close to cool the wafer in the load-lock chamber.
